(19) United States
(12) Patent Application Publication
(10) Pub. No.: US 2025/0291001 A1
(43) Pub. Date: Sep. 18, 2025

(54) TECHNOLOGIES FOR NON-DESTRUCTIVELY AND IN-SITU MONITORING FOR CORROSION IN OBJECT

(71) Applicants: AUBURN UNIVERSITY, Auburn, AL (US); The United States of America as Represented by the Administrator of the National Aeronautics & Space, Washington, DC (US)

(72) Inventors: Zhongyang CHENG, Auburn, AL (US); Terry Dewayne ROLIN, MFSC, AL (US); Yaqub ADEDIJI, Auburn, AL (US); Jindong WEI, Auburn, AL (US)

(21) Appl. No.: 19/069,649

(22) Filed: Mar. 4, 2025

Related U.S. Application Data
(60) Provisional application No. 63/565,164, filed on Mar. 14, 2024.

(51) Int. Cl. G01R 31/58

(52) U.S. Cl. CPC G01R 31/58

(57) ABSTRACT

Technologies for nondestructively detecting corrosion of an object include a measurement device such as a vector network analyzer (VNA) and a computing device coupled to the measurement device. An object such as a metallic cable is coupled to the measurement device, multiple S-parameter values for the object are measured over a predetermined frequency range. The range may be between 40 MHz to 1 GHz. The S-parameter values may include forward gain/loss (S₂₁) and input impedance (S₁₁). The computing device counts a number of peaks in the S-parameter values and determines an indication of corrosion for the object based on the number of peaks. The indication of corrosion is proportional to the number of peaks. Counting the peaks may include smoothing the S-parameter values, determining a first order derivative, transforming the derivative to a frequency domain signal, and counting peaks in the frequency domain signal. Other embodiments are described and claimed.

### CROSS-REFERENCE TO RELATED APPLICATION

This application claims priority to U.S. Provisional Application Ser. No. 63/565,164, filed Mar. 14, 2024, the entire disclosure of which is hereby incorporated by reference. Additionally, cross-reference is made to co-pending U.S. application Ser. No. 18/370,138, filed Sep. 19, 2023.

### STATEMENT REGARDING FEDERALLY SPONSORED RESEARCH

This invention was made with Government support under 80NSSC21M0288 awarded by the National Aeronautics and Space Administration (NASA). The Government has certain rights in the invention.

### BACKGROUND

Corrosion occurs when a chemical reaction takes place in an environment that surrounds a material (e.g., cables, wires) which initiates/causes a slow deterioration and weakening of the material over time. Water, H₂, O₂, an electric current, dirt, or bacteria located in the environment that comes in contact with a material, such as metal in a cable, undergoes an electrochemical reaction resulting in corrosion. The type of metal used in wire/cable construction (e.g., copper), the type of insulating material, and the amount/duration of exposure to H₂O or O₂, or other material will ultimately determine the rate and form of corrosion (e.g., pitting, generalized/uniform, crevice, intergranular, stress corrosion cracking, galvanic). In 2013, the National Association of Corrosion Engineers (NACE) estimated that on a global basis, the detrimental effects of corrosion of all types cost the industry/consumers $2.5 trillion.

Corrosion, either internal to a wire or on its surface in electrical components, wiring systems, electronics, and wire harnesses (e.g., flight harnesses), can affect the product's ability to function properly/transmit an electric signal. Specific to flight harnesses (e.g., NASA, space-grade), red plague (cuprous oxide corrosion) can develop in silver-coated soft or annealed copper conductors (component leads, single and multi-stranded wires, printed circuit board (PCB) conductors) when a galvanic cell forms between the copper base metal and the silver coating in the presence of H₂O and O₂. As a result, the silver plating is damaged, exposing the copper wire to H₂O or high temperatures, making it susceptible to corrosion. The copper wire begins to corrode, resulting in irreversible destruction, with the copper eventually dissolving completely, leaving behind the damaged silver-plating shell. The sliver plating alone cannot perform without the copper wire interior, thus rendering the wire nonfunctional. NASA has developed red plague control plans (RPCP) to prevent/mitigate the harmful effects of this type of corrosion on flight harnesses which focus on a variety of issues, assuring that the strand materials and coatings are manufactured in accordance with recognized ASTM or ANSI standards, use of qualified/approved suppliers/OEM, not using/storing procured wires/cables that are greater than 10 years old, protecting silver-coated wire/cables from environmental conditions which can cause red plague, proper shipping/packaging techniques, and use of stringent assembly/quality control techniques.

To assess the health of flight/wire harnesses, typical tests include a range of pre-operative/manufacturing techniques such as build tests (e.g., cable/wire length, routing ability), electrical measurements (e.g., insulation, dielectric, and/or contact resistance), mechanical assessments (stress, immersion), product durability (connector mating/de-mating) evaluations, and environmental (e.g., thermal, moisture resistance, vibration, O₃ exposure, mildew resistance) tests. Corrosion testing of such harness systems was also identified for use in a pre-operative mode; AS4373 Method 60811 to quantify fluoride evolution to assess the likelihood of red plague, AS4373 Method 610, AS4373 Method 611, and AS4373 Method 61212. From an as-built perspective, standard corrosion tests of the destructive variety were identified, which primarily include optical microscopy techniques and scanning electron microscope (SEM) to gauge wire corrosion which is performed under laboratory conditions. No technique was identified allowing for corrosion identification of wires/cables in a harness in an in-situ mode.

### SUMMARY

According to one aspect of the disclosure, a system for nondestructively detecting corrosion of an object includes a measurement device and a computing device coupled to the measurement device. The computing device comprises a scattering parameter manager, a peak counter, and a corrosion modeler. The scattering parameter manager is to measure, with the measurement device, a plurality of S-parameter values for a device under test over a first predetermined frequency range, wherein the device under test comprises the object. The peak counter is to count a first number of peaks in the plurality of S-parameter values over the first predetermined frequency range. The corrosion modeler is to determine an indication of corrosion of the device under test based on the first number of peaks, wherein the indication of corrosion is proportional to the number of peaks.

In an embodiment, the object comprises a metallic cable or wire. In an embodiment, the object comprises a silver-coated copper cable.

In an embodiment, the object is connected in situ to the measurement device. In an embodiment, the measurement device comprises a vector network analyzer. In an embodiment, the plurality of S-parameter values comprises a plurality of magnitudes of a forward gain/loss (S₂₁). In an embodiment, the plurality of S-parameter values comprises a plurality of magnitudes of an input impedance (S₁₁).

In an embodiment, the first predetermined frequency range comprises between 40 MHz to 1 GHz. In an embodiment, the first predetermined frequency rage comprises between 40 MHz to 100 MHz, between 100 MHz to 500 MHz, or between 500 MHz to 1 GHz.

In an embodiment, to count the first number of peaks comprises to smooth the plurality of S-parameter values to generate smoothed S-parameter values; determine a first order derivative of the smoothed S-parameter values; transform the first order derivative to a frequency domain signal with a fast Fourier transform; and count the first number of peaks in the frequency domain signal. In an embodiment, to smooth the plurality of S-parameter values comprises to smooth the plurality of S-parameter values with an adjacent averaging technique.

In an embodiment, to determine the indication of corrosion of the device under test based on the first number of peaks comprises to compare the first number of peaks to an initial number of peaks measured for the device under test. In an embodiment, to determine the indication of corrosion of the device under test based on the first number of peaks comprises to compare the first number of peaks to a reference number of peaks associated with an uncorroded device.

According to another aspect, a method for nondestructively detecting corrosion of an object includes measuring, by a computing device, a plurality of S-parameter values for a device under test over a first predetermined frequency range, wherein the device under test comprises the object; counting, by the computing device, a first number of peaks in the plurality of S-parameter values over the first predetermined frequency range; and determining, by the computing device, an indication of corrosion of the device under test based on the first number of peaks, wherein the indication of corrosion is proportional to the number of peaks.

In an embodiment, the object comprises a metallic cable or wire. In an embodiment, the object comprises a silver-coated copper cable.

In an embodiment, the method further includes connecting the object in situ to a measurement device, wherein measuring the plurality of S-parameter values comprises measuring the plurality of S-parameter values with the measurement device. In an embodiment, the measurement device comprises a vector network analyzer. In an embodiment, the plurality of S-parameter values comprises a plurality of magnitudes of a forward gain/loss (S₂₁). In an embodiment, the plurality of S-parameter values comprises a plurality of magnitudes of an input impedance (S₁₁).

In an embodiment, the first predetermined frequency range comprises between 40 MHz to 1 GHz. In an embodiment, the first predetermined frequency rage comprises between 40 MHz to 100 MHz, between 100 MHz to 500 MHz, or between 500 MHz to 1 GHz.

In an embodiment, counting the first number of peaks includes smoothing the plurality of S-parameter values to generate smoothed S-parameter values; determining a first order derivative of the smoothed S-parameter values; transforming the first order derivative to a frequency domain signal with a fast Fourier transform; and counting the first number of peaks in the frequency domain signal. In an embodiment, smoothing the plurality of S-parameter values comprises smoothing the plurality of S-parameter values with an adjacent averaging technique.

In an embodiment, determining the indication of corrosion of the device under test based on the first number of peaks comprises comparing the first number of peaks to an initial number of peaks measured for the device under test. In an embodiment, determining the indication of corrosion of the device under test based on the first number of peaks comprises comparing the first number of peaks to a reference number of peaks associated with an uncorroded device.

### BRIEF DESCRIPTION OF THE DRAWINGS

The concepts described herein are illustrated by way of example and not by way of limitation in the accompanying figures. For simplicity and clarity of illustration, elements illustrated in the figures are not necessarily drawn to scale. Where considered appropriate, reference labels have been repeated among the figures to indicate corresponding or analogous elements.

FIG. 1 is a simplified block diagram of at least one embodiment of a system for non-destructive, in-situ corrosion monitoring;

FIG. 2 is a schematic diagram illustrating S-parameter measurement that may be performed by the system of FIG. 1;

FIG. 3 is a simplified block diagram of an environment that may be established by a computing device of FIG. 1;

FIG. 4 is a simplified flow diagram of at least one embodiment of a method for non-destructive, in-situ corrosion monitoring that may be executed by the computing device of FIGS. 1 and 3;

FIG. 5 is a schematic diagram illustrating frequency ranges that may be measured by the system of FIG. 1;

FIG. 6 is a chart illustrating S-parameter measurements that may be captured by the system of FIG. 1;

FIG. 7 is a chart illustrating experimental results that may be achieved by the system of FIG. 1; and

FIG. 8 is a chart illustrating additional experimental results that may be achieved by the system of FIG. 1.

### DETAILED DESCRIPTION OF THE DRAWINGS

While the concepts of the present disclosure are susceptible to various modifications and alternative forms, specific embodiments thereof have been shown by way of example in the drawings and will be described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

References in the specification to “one embodiment,” “an embodiment,” “an illustrative embodiment,” etc., indicate that the embodiment described may include a particular feature, structure, or characteristic, but every embodiment may or may not necessarily include that particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described. Additionally, it should be appreciated that items included in a list in the form of “at least one A, B, and C” can mean (A); (B); (C); (A and B); (A and C); (B and C); or (A, B, and C). Similarly, items listed in the form of “at least one of A, B, or C” can mean (A); (B); (C); (A and B); (A and C); (B and C); or (A, B, and C).

The disclosed embodiments may be implemented, in some cases, in hardware, firmware, software, or any combination thereof. The disclosed embodiments may also be implemented as instructions carried by or stored on a transitory or non-transitory machine-readable (e.g., computer-readable) storage medium, which may be read and executed by one or more processors. A machine-readable storage medium may be embodied as any storage device, mechanism, or other physical structure for storing or transmitting information in a form readable by a machine (e.g., a volatile or non-volatile memory, a media disc, or other media device).

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features.

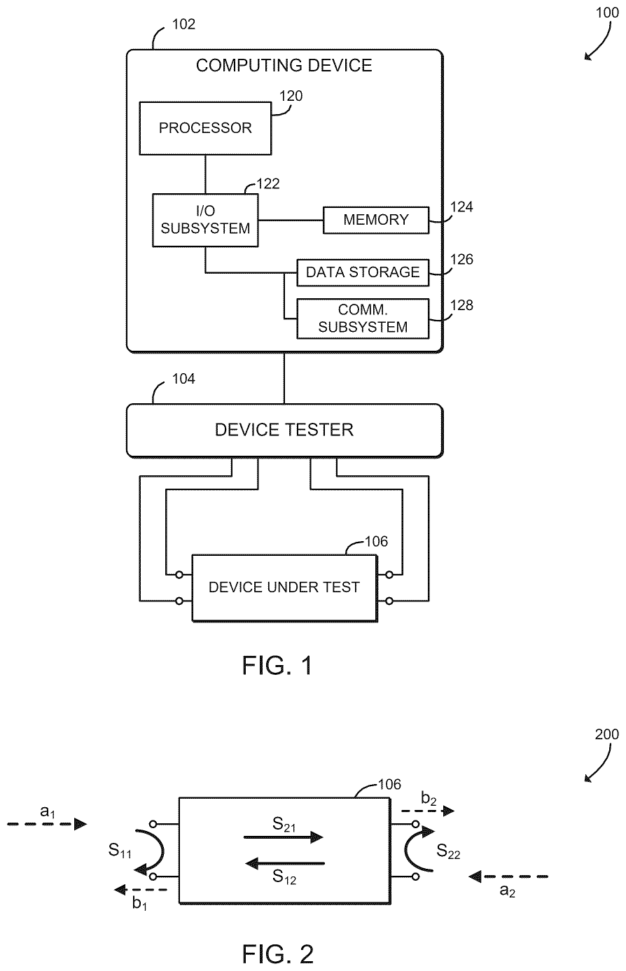

Referring now to FIG. 1, an illustrative system 100 for non-destructive, in-situ corrosion monitoring includes a computing device 102 and in some embodiments a device tester 104 that may be coupled to a device under test 106. The device under test 106 may include a cable or wire, such as a silver-plated copper cable, and may be included in a flight harness or other device. In use, as described further below, the computing device 102 with the device tester 104 measures one or more S-parameter values over a frequency range in which the S-parameter value is sensitive to corrosion. The computing device 102 counts a number of peaks within the measured S-parameter values and, based on the counted number of peaks, determines whether corrosion is present and/or a degree of corrosion that is present. Thus, the system 100 allows for non-destructive detection of corrosion in the device under test. Additionally, the system 100 may while the device under test 106 is in situ; that is, the system 100 may be used to test cables included in a flight harness or other device without disassembling or destroying the flight harness. Accordingly, the system 100 provides the advantage of non-destructive, in-situ corrosion monitoring for devices such as cables in flight harnesses, as compared to previous techniques which required destructive testing of cables.

As shown in FIG. 1, the computing device 102 may be embodied as any type of device capable of performing the functions described herein. For example, the computing device 102 may be embodied as, without limitation, a workstation, a server computer, a desktop computer, a laptop computer, a network appliance, a web appliance, a smartphone, a tablet computer, a consumer electronic device, a distributed computing system, a multiprocessor system, and/or any other computing device capable of performing the functions described herein. As shown in FIG. 1, the illustrative computing device 102 includes a processor 120, an I/O subsystem 122, memory 124, a data storage device 126, and communication circuitry 128. Of course, the computing device 102 may include other or additional components, such as those commonly found in a computer workstation (e.g., various input/output devices), in other embodiments. Additionally, in some embodiments, one or more of the illustrative components may be incorporated in, or otherwise form a portion of, another component. For example, the memory 124, or portions thereof, may be incorporated in the processor 120 in some embodiments. Additionally, in some embodiments, the computing device 102 may be embodied as a “virtual server” formed from multiple computing devices distributed across a network and operating in a public or private cloud. Accordingly, although the computing device 102 is illustrated in FIG. 1 as embodied as a single computing device, it should be appreciated that the computing device 102 may be embodied as multiple devices cooperating together to facilitate the functionality described below.

The processor 120 may be embodied as any type of processor or compute engine capable of performing the functions described herein. For example, the processor may be embodied as a single or multi-core processor(s), digital signal processor, microcontroller, or other processor or processing/controlling circuit. Similarly, the memory 124 may be embodied as any type of volatile or non-volatile memory or data storage capable of performing the functions described herein. In operation, the memory 124 may store various data and software used during operation of the computing device 102 such as operating systems, applications, programs, libraries, and drivers. The memory 124 is communicatively coupled to the processor 120 via the I/O subsystem 122, which may be embodied as circuitry and/or components to facilitate input/output operations with the processor 120, the memory 124, and other components of the computing device 102. For example, the I/O subsystem 122 may be embodied as, or otherwise include, memory controller hubs, input/output control hubs, firmware devices, communication links (i.e., point-to-point links, bus links, wires, cables, light guides, printed circuit board traces, etc.) and/or other components and subsystems to facilitate the input/output operations. In some embodiments, the I/O subsystem 122 may form a portion of a system-on-a-chip (SoC) and be incorporated, along with the processor 120, the memory 124, and other components of the computing device 102, on a single integrated circuit chip.

The data storage device 126 may be embodied as any type of device or devices configured for short-term or long-term storage of data such as, for example, memory devices and circuits, memory cards, hard disk drives, solid-state drives, or other data storage devices. The communication circuitry 128 of the computing device 102 may be embodied as any communication circuit, device, or collection thereof, capable of enabling communications between the computing device 102, the third-party device 106, the computing device 102, and/or other remote devices. The communication circuitry 128 may be configured to use any one or more communication technology (e.g., wireless or wired communications) and associated protocols (e.g., Ethernet, Bluetooth®, Wi-Fi®, WiMAX, etc.) to effect such communication.

The device tester 104 may be embodied as a vector network analyzer (VNA), network analyzer, oscilloscope, or other device capable of measuring S-parameters of the device under test 106 and otherwise performing the operations described herein. In some embodiments, one or more functions of the device tester 104 may be incorporated in or otherwise performed by another device, such as the computing device 102.

Referring now to FIG. 2, schematic diagram 200 illustrates the S-parameters for the device under test 106, which may be measured by the device tester 104. As shown, the device under test 106, such as a silver-plated copper cable, may be modeled as a two-port network. The device tester 104, which is illustratively a VNA, may be used to measure one or more S-parameters (also called scattering parameters) of the device under test 106, including S₁₁, S₁₂, S₂₂, and S₂₁ as shown in FIG. 2. S₁₁ measures input impedance, S₁₂ measures output match/impedance, S₂₁ measures forward gain/loss, and S₂₂ measures reverse gain/loss, of the device/cable 106, respectively. The device tester 104 may measure one or more of the S-parameters at multiple frequencies. Those frequencies may cover one or more predetermined frequency ranges, as described further below.

As described further below, interference may be generated in output S-parameter signals (S₁₁, S₁₂, S₂₁, and/or S₂₂) measured for a device under test 106 such as a cable due to interactions of the waves/signals with dirty connections and/or corroded spots on the cable across different frequency ranges. As described below, the magnitude of interference in the S-parameter signals is proportional to the amount, area, and depth of corrosion spots on the cable. This proportional relationship indicates that higher levels of interference would indicate greater corrosion, and vice versa. Accordingly, by analyzing these signals as described below, the system 100 may discern meaningful information about the extent of corrosion on the cable, which provides a non-destructive method of representing corrosion status in the cable.

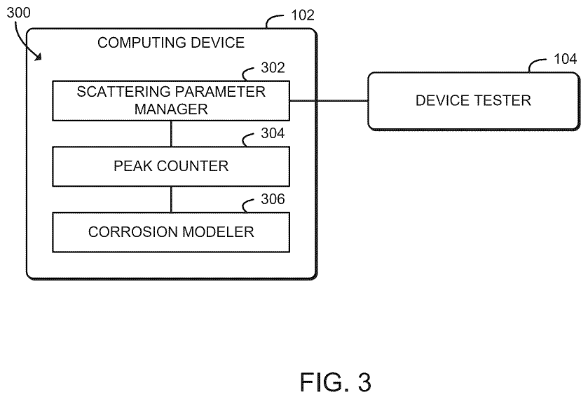

Referring now to FIG. 3, in the illustrative embodiment, the computing device 102 establishes an environment 300 during operation. The illustrative environment 300 includes a scattering parameter manager 302, a peak counter 304, and a corrosion modeler 306. The various components of the environment 300 may be embodied as hardware, firmware, software, or a combination thereof. As such, in some embodiments, one or more of the components of the environment 300 may be embodied as circuitry or a collection of electrical devices (e.g., scattering parameter manager circuitry 302, peak counter circuitry 304, and/or corrosion modeler circuitry 306). It should be appreciated that, in such embodiments, one or more of those components may form a portion of the processor, the I/O subsystem, and/or other components of the computing device 102.

The scattering parameter manager 302 is configured to measure, with a measurement device such as the device tester 104, S-parameter values for a device under test 106 over a predetermined frequency range. As described above, the device under test 106 may be embodied as an object such as a metallic cable or wire, including a silver-coated copper cable. In some embodiments, the object may be connected in situ to the measurement device. As described above, in some embodiments the measurement device may be a vector network analyzer (VNA). In some embodiments, the S-parameter values may include multiple magnitudes of a forward gain/loss (S₂₁) and/or multiple magnitudes of an input impedance (S₁₁). The predetermined frequency range may be between 40 MHz to 1 GHz, and in some embodiments may be between 40 MHz to 100 MHz, between 100 MHz to 500 MHz, and/or between 500 MHz to 1 GHz.

The peak counter 304 is configured to count a number of peaks in the S-parameter values over the predetermined frequency range. In some embodiments, counting the number of peaks may include smoothing the S-parameter values to generate smoothed S-parameter values, determining a first order derivative of the smoothed S-parameter values, transforming the first order derivative to a frequency domain signal with a fast Fourier transform, and counting the number of peaks in the frequency domain signal. In some embodiments, smoothing the plurality of S-parameter values may include smoothing the plurality of S-parameter values with an adjacent averaging technique.

The corrosion modeler 306 is configured to determine an indication of corrosion of the device under test 106 based on the counted number of peaks. The indication of corrosion is proportional to the number of peaks. In some embodiments, determining the indication of corrosion of the device based on the number of peaks may include comparing the first number of peaks to an initial number of peaks measured for the device. In some embodiments, determining the indication of corrosion of the device based on the number of peaks may include comparing the first number of peaks to a reference number of peaks associated with an uncorroded device.

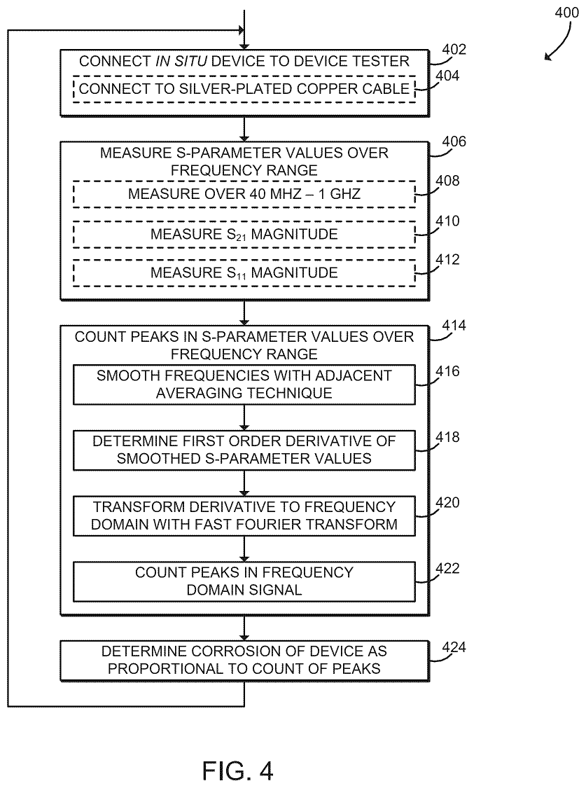

Referring now to FIG. 4, in use, the computing device 102 may execute a method 400 for non-destructive corrosion monitoring. It should be appreciated that, in some embodiments, the operations of the method 400 may be performed by one or more components of the environment 300 of the computing device 102 as shown in FIG. 3. The method 400 begins with block 402, in which the device under test 106 is connected to the device tester 104. As described above, the device under test 106 may be a wire or cable and in some embodiments may be included in a flight harness. Additionally or alternatively, in some embodiments, the device tester 104 may be connected to the device under test 106 while the device under test 106 is in situ. For example, the device under test 106 may remain included in a flight harness, which in some embodiments may remain incorporated in a space vehicle or other device. In some embodiments, in block 404 the device tester 104 may connect to a silver-plated copper cable, which is the device under test 106.

In block 406, the computing device 102 measures S-parameter values for one or more of the S-parameter values for the device under test 106 over a frequency range. The S-parameter values may be measured by the device tester 104, which is illustratively a vector network analyzer (VNA). The VNA may provide the measured S-parameter values to the computing device 102, and/or in some embodiments the VNA may be controlled by the computing device 102. In some embodiments, in block 408 the computing device 102 may measure S-parameter values over a frequency range from 40 MHz to 1 GHz. As described further below, it has been determined that this frequency range is sufficiently sensitive to the effects of corrosion without being affected by other factors such as humidity, temperature, excessive noise, or other measurement difficulties. Of course, it should be understood that in other embodiments, the S-parameter values may be measured over one or more other frequency ranges or sub-ranges, such as 40 MHz-100 MHZ, 100 MHz-500 MHz, 500 MHz-1 GHz, or another frequency range or sub-range.

As an example, each of the different frequency sub-ranges may be sensitive to corrosion at a particular cross-section of a cable. Continuing that example, due to skin effect, the electric field of an electronic signal carried by an object such as a cable is concentrated in the layer near its surface. The higher the frequency of the electronic signal, the stronger the skin effect. Accordingly, higher-frequency subranges may be more sensitive to corrosion near the surface of the cable, and lower-frequency subranges may be more sensitive to corrosion further from the surface of the cable.

As described above, when the device under test 106 is modeled as a two-port network, there are four potential S-parameter values, including S₁₁, S₁₂, S₂₂, and S₂₁. Each of those S-parameter values is, in turn, a complex number, and thus includes a magnitude and a phase. The computing device 102 may measure any one or more of those S-parameter values in embodiments. In some embodiments, in block 410 the computing device 102 may measure S₂₁ magnitude over the frequency range. The S-parameter value S₂₁ corresponds to forward gain/loss. In some embodiments, in block 412 the computing device 102 may measure S₁₁ magnitude over the frequency range. The S-parameter value S₁₁ corresponds to input impedance.

In block 414, the computing device 102 counts peaks in the S-parameter values over the measured frequency range. The computing device 102 may use any appropriate technique to count peaks in the S-parameter value. Illustratively, in block 416 the computing device 102 smooths S-parameter values using an adjacent averaging technique. In block 418, the computing device 102 determines a first order derivative of the smoothed S-parameter values. In block 420, the computing device 102 transforms the derivative values to the frequency domain using a fast Fourier transform (FFT). In block 422, the computing device 102 counts peaks in the frequency domain signal. The computing device 102 may use any appropriate peak-counting algorithm or other technique.

After counting the peaks, in block 424, the computing device 102 determines corrosion of the device under test 102 as proportional to the count of peaks. That is, the computing device 102 determines that, as the count of peaks increases, the level of corrosion of the device 102 also increases. In some embodiments, the number of peaks may be proportional to the amount, area, and depth of corrosion spots on the device under test 106 (e.g., a cable). The computing device 102 may use any technique to qualify or quantify the determined corrosion of the device. For example, the computing device 102 may determine whether corrosion is present or not present, the computing device 102 may determine a relative level of corrosion (e.g., low, medium, high, etc.), and/or the computing device 102 may provide another quantification of a level of corrosion of the device under test 106. To determine the level of corrosion, the computing device 102 may, for example, compare the count of peaks to a previously determined count of peaks for a device without corrosion or otherwise in an uncorroded state. The device without corrosion may be the device under test 106, for example at the time of construction, installation, or integration, or may be embodied as a different device (e.g., an uncorroded reference device). After determining corrosion for the device under test 106, the method 400 loops back to block 402, in which the computing device 102 may continue monitoring the device under test 106 and/or other devices for corrosion.

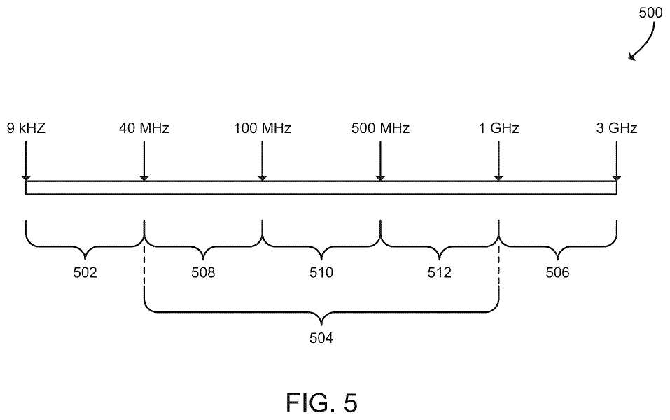

Referring now to FIG. 5, schematic diagram 500 illustrates one potential embodiment of frequency ranges that may be measured for S-parameters by the system 100. Note that the diagram 500 is not to scale. As shown, a frequency range from about 9 kHz to about 3 GHz includes a low range 502 from about 9 kHz to about 40 MHz, a middle range 504 from about 40 MHz to about 1 GHz, and a high range 506 from about 1 GHz to about 3 GHz or above. The middle range 504 is further subdivided into subrange 508 from about 40 MHz to about 100 MHZ, a subrange 510 from about 100 MHz to about 500 MHz, and a subrange 512 from about 500 MHz to about 1 GHz.

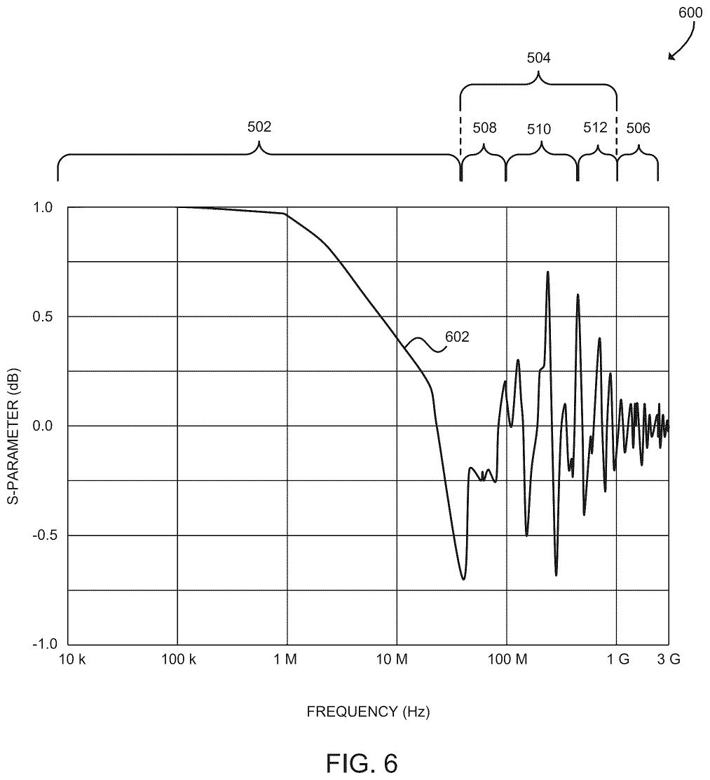

Referring now to FIG. 6, chart 600 illustrates S-parameter values for a device under test 106 for the entire frequency range from about 9 kHz to 3 GHZ. Curve 602 represents S-parameter values for the magnitude of parameter S₂₁ (forward gain/loss), and is illustrated in decibels (dB). The curve 602 shown in FIG. 6 represents S-parameter measurements made for a new device 106, and thus illustrates potential S-parameter values for a device without any appreciable amount of corrosion. As shown, in the low range 502, the signal 602 does not include any peaks, and is thus may not be sufficiently sensitive to effects of corrosion. In the high range 506, the signal 602 includes too many peaks, and thus may be difficult to use to obtain reliable measurements. For example, the high range 506 may be overly sensitivity to many detailed aspects of corrosion in the cable and may not be used for monitoring corrosion. In the middle range 504, the signal 602 is sufficiently sensitive without including too many peaks. Accordingly, in some embodiments, the system 100 may measure S-parameter values over the middle frequency range 504 and/or one or more of the subranges 508, 510, 512 included in the middle frequency range 504.

### EXAMPLES

In an experiment, sets of 12-inch long silver-coated copper cables with soldered joints were placed in wet and dry conditions at room temperature for extended periods of time. The wet cables were kept in a KNO₃ salt saturated solution. S-parameter readings (S₂₁) were measured for the entire frequency spectrum (9 kHz to 3 GHZ) on a monthly basis for 18 months.

Initially, the S-parameter readings for the cables in wet and dry conditions were the same in all frequency ranges at the start of the experiment, as illustrated in FIG. 6. After the 18-months corrosion time point, the S-parameter readings (S₂₁) of the wet and dry solder joints showed no difference in a frequency range from 9 kHz to 10 MHz. This result shows that corrosion does not affect the S-parameter readings of the cables in this range. Therefore, the rate of corrosion of the cables in wet and dry conditions has no influence on the S-parameter readings of the cables in the low frequency range. But it was also observed that the difference in the S-parameter between the dry and wet cables increased with increasing frequency.

After the 18-months corrosion time point, the S-parameter readings (S₂₁) of the cables in the wet and dry conditions showed a clear difference in a frequency range from 10 MHz to 100 MHz. This result shows that corrosion of the cables affects the A-parameter readings of the cables. Therefore, the rate of corrosion of cables in the wet condition has a slightly different influence on the on the S-parameter readings than the dry condition in this medium frequency range. Similarly, after the 18-months corrosion time point, the S-parameter readings (S₂₁) of the cables in the wet and dry conditions showed a clear difference in a frequency range from 100 MHz to 600 MHz. This result shows that corrosion of the cables affects the S-parameter readings of the conductors. Therefore, the rate of corrosion of cables in the wet condition has a slightly different influence on the on the S-parameter readings than the dry condition in the 100 MHZ-600 MHZ frequency range. Additionally, after the 18-months corrosion time point, the S-parameter readings (S₂₁) of the wet and dry solder joints showed a considerable difference in a medium frequency range 600 MHz to 3 GHz. This result shows that corrosion affects the S-parameter readings of the cables. Therefore, the rate of corrosion of cables in the wet condition also has a slightly different influence on the on the S-parameter readings than the dry condition in the high frequency range. However, there are too many peaks in the S-parameter results in this frequency range for effective measurement of corrosion.

As described above, the roughness and number of peaks of the S-parameter signals increases as the corrosion time point increases. As described above, the method 400 performed by the system 100 may numerically characterize this roughness in the S-parameter signals, which establishes a technique for representing the corrosion status in the cables.

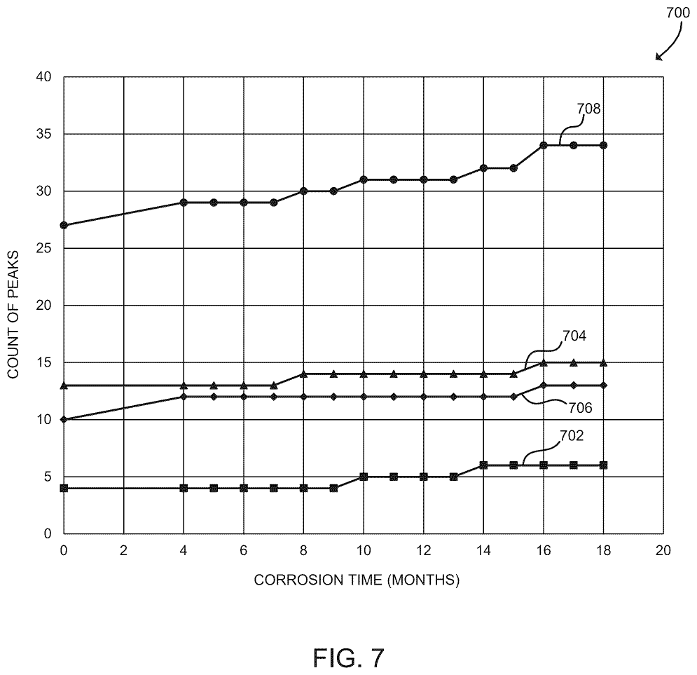

Referring now to FIG. 7, chart 700 illustrates experimental results that may be achieved with the system 100. As described above, in order to count the number of peaks in the S-parameter readings as corrosion time point increases, the measured frequency ranges were divided into frequency ranges 9 kHz-40 MHz, 40 MHz-100 MHz, 100 MHz-500 MHz, 500 MHz-1 GHz and 1 GHz-3 GHz. However, as described above, the 9 kHz-40 MHz range contained very few peaks, and the 1 GHz-3 GHz range contains too many peaks. Accordingly, the chart 700 illustrates peaks counted in the 40 MHz-1 GHz frequency range.

In particular, the chart 700 illustrates peaks counted in the S₁₁ S-parameter readings determined by the system 100 as described above in connection with the method 400. Curve 702 shows the number of peaks in the frequency range 40 MHz-100 MHz over corrosion time points from zero to 18 months. Curve 704 shows the number of peaks in the frequency range 100 MHz-500 MHz over corrosion time points from zero to 18 months. Curve 706 shows the number of peaks in the frequency range 500 MHz-1 GHz over corrosion time points from zero to 18 months. Curve 708 shows the total number of peaks for all of the sub-ranges from 40 MHz-1 GHz. As shown, the number of peaks for each of the sub-ranges as well as for the entire frequency range 40 MHz-1 GHz increases over time as corrosion increases. Accordingly, the number of peaks may be used to determine the level of corrosion as described above.

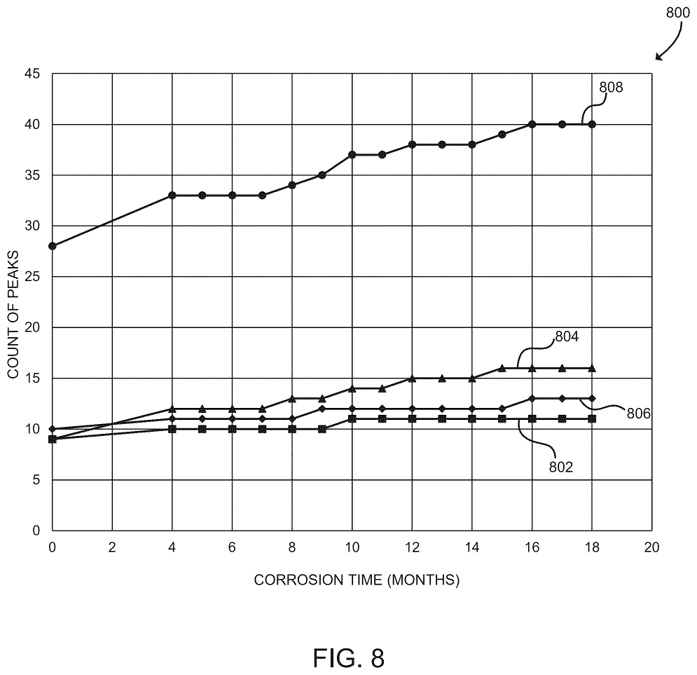

Referring now to FIG. 8, chart 800 illustrates additional experimental results that may be achieved with the system 100. The chart 800 illustrates peaks counted in the S₂₁ S-parameter readings determined by the system 100 as described above in connection with the method 400. Curve 802 shows the number of peaks in the frequency range 40 MHz-100 MHZ over corrosion time points from zero to 18 months. Curve 804 shows the number of peaks in the frequency range 100 MHz-500 MHz over corrosion time points from zero to 18 months. Curve 806 shows the number of peaks in the frequency range 500 MHz-1 GHz over corrosion time points from zero to 18 months. Curve 808 shows the total number of peaks for all of the sub-ranges from 40 MHz-1 GHz. As shown, the number of peaks for each of the sub-ranges as well as for the entire frequency range 40 MHz-1 GHz increases over time as corrosion increases. Accordingly, the number of peaks may be used to determine the level of corrosion as described above.

In order to simulate the effect of corrosion in cables on S-parameter readings, corrosion equivalent circuits may be used in Advanced Design System (ADS) to model the corrosion in the cables. Corrosion equivalent circuits are simplified electrical models used to represent the electrochemical processes involved in corrosion. An ideal cable is known to be purely resistive with negligible inductance or capacitance effects. However, corrosion can create bends or localized areas of different electrical conductivity on the cable surface, which could result in the formation of small capacitances between the corroded regions and the unaffected areas. In some cases, corrosion could cause the formation of localized loops or irregularities on the cable surface. These features might introduce inductance due to their geometry. This capacitance and inductance due to corrosion is expected to cause modifications in the S-parameter readings such as attenuation, increase in roughness and number of peaks.

Corrosion may also induce rectifying effects. For example, when a metal surface is coated with a thin layer of oxide, it can exhibit rectifying properties, allowing current flow in one direction more readily than in the opposite direction. Further, corrosion can create localized areas of high electrical resistance, particularly in the form of corrosion products or oxide layers. These high resistance paths can impact the flow of electric current, leading to voltage drops, signal degradation, or increased power losses in the cables.

In an experiment, an equivalent circuit of a metal under coating such as a silver-plated copper cable was simulated. An increase in corrosion in the cable was depicted by adding additional capacitors and inductors in series and parallel with the equivalent circuit model of the plated cable, and the circuit with simulated corrosion was simulated. The simulation resulted in modifications in the S-parameter readings and the number of peaks in the S-parameter readings increased, for example in the 100 MHz-600 MHz frequency range.

1. A system for nondestructively detecting corrosion of an object, the system comprising:
a measurement device; and
a computing device coupled to the measurement device, wherein the computing device comprises:
a scattering parameter manager to measure, with the measurement device, a plurality of S-parameter values for a device under test over a first predetermined frequency range, wherein the device under test comprises the object;
a peak counter to count a first number of peaks in the plurality of S-parameter values over the first predetermined frequency range; and
a corrosion modeler to determine an indication of corrosion of the device under test based on the first number of peaks, wherein the indication of corrosion is proportional to the number of peaks.

2. The system of claim 1, wherein the object comprises a metallic cable or wire.

3. The system of claim 2, wherein the object comprises a silver-coated copper cable.

4. The system of claim 1, the object is connected in situ to the measurement device.

5. The system of claim 4, wherein the measurement device comprises a vector network analyzer.

6. The system of claim 1, wherein the plurality of S-parameter values comprises a plurality of magnitudes of a forward gain/loss (S₂₁).

7. The system of claim 1, wherein the plurality of S-parameter values comprises a plurality of magnitudes of an input impedance (S₁₁).

8. The system of claim 1, wherein the first predetermined frequency range comprises between 40 MHz to 1 GHz.

9. The system of claim 8, wherein the first predetermined frequency rage comprises between 40 MHz to 100 MHz, between 100 MHz to 500 MHz, or between 500 MHz to 1 GHz.

10. The system of claim 1, wherein to count the first number of peaks comprises to:
smooth the plurality of S-parameter values to generate smoothed S-parameter values;
determine a first order derivative of the smoothed S-parameter values;
transform the first order derivative to a frequency domain signal with a fast Fourier transform; and
count the first number of peaks in the frequency domain signal.

11. The system of claim 1, wherein to smooth the plurality of S-parameter values comprises to smooth the plurality of S-parameter values with an adjacent averaging technique.

12. The system of claim 1, wherein to determine the indication of corrosion of the device under test based on the first number of peaks comprises to compare the first number of peaks to an initial number of peaks measured for the device under test.

13. The system of claim 1, wherein to determine the indication of corrosion of the device under test based on the first number of peaks comprises to compare the first number of peaks to a reference number of peaks associated with an uncorroded device.

14. A method for nondestructively detecting corrosion of an object, the method comprising:
measuring, by a computing device, a plurality of S-parameter values for a device under test over a first predetermined frequency range, wherein the device under test comprises the object;
counting, by the computing device, a first number of peaks in the plurality of S-parameter values over the first predetermined frequency range; and
determining, by the computing device, an indication of corrosion of the device under test based on the first number of peaks, wherein the indication of corrosion is proportional to the number of peaks.

15. The method of claim 14, further comprising connecting the object in situ to a measurement device, wherein measuring the plurality of S-parameter values comprises measuring the plurality of S-parameter values with the measurement device.

16. The method of claim 14, wherein the first predetermined frequency range comprises between 40 MHz to 1 GHz.

17. The method of claim 14, wherein counting the first number of peaks comprises:
smoothing the plurality of S-parameter values to generate smoothed S-parameter values;
determining a first order derivative of the smoothed S-parameter values;
transforming the first order derivative to a frequency domain signal with a fast Fourier transform; and
counting the first number of peaks in the frequency domain signal.

18. One or more non-transitory, computer-readable storage media comprising a plurality of instructions that in response to being executed cause a computer device to:
measure a plurality of S-parameter values for a device under test over a first predetermined frequency range;
count a first number of peaks in the plurality of S-parameter values over the first predetermined frequency range; and
determine an indication of corrosion of the device under test based on the first number of peaks, wherein the indication of corrosion is proportional to the number of peaks.

19. The one or more non-transitory, computer-readable storage media of claim 18, wherein the first predetermined frequency range comprises between 40 MHz to 1 GHz.

20. The one or more non-transitory, computer-readable storage media of claim 18, wherein to count the first number of peaks comprises to:
smooth the plurality of S-parameter values to generate smoothed S-parameter values;
determine a first order derivative of the smoothed S-parameter values;
transform the first order derivative to a frequency domain signal with a fast Fourier transform; and
count the first number of peaks in the frequency domain signal.
